(19) United States
(12) Patent Application Publication
(10) Pub. No.: US 2012/0040503 A1
(43) Pub. Date: Feb. 16, 2012

(54) FABRICATION METHOD OF INTEGRATING POWER TRANSISTOR AND SCHOTTKY DIODE ON A MONOLITHIC SUBSTRATE

(75) Inventor: KAO-WAY TU, Taipei County (TW)

(73) Assignee: GREAT POWER SEMICONDUCTOR CORP., TAIPEI COUNTY (TW)

(21) Appl. No.: 12/854,280

(22) Filed: Aug. 11, 2010

(51) Int. Cl. H01L 21/8234

(52) U.S. Cl. 438/237; 257/E21.616

(57) ABSTRACT

A fabrication method of integrating a power transistor and a schottky diode on a monolithic substrate is provided. Firstly, a substrate of a first conductive type is provided. Then, at least a polysilicon gate and a second polysilicon structure are formed on the substrate. At least a portion of the second polysilicon structure is located on an upper surface of the substrate. Thereafter, a body of a second conductive type and a source region of the first conductive type are formed between the polysilicon gate and the second polysilicon structure. Then, an interlayer dielectric film is formed on the polysilicon gate to define a source contact window, but the second polysilicon structure is still exposed. Afterward, a portion of the second polysilicon structure is removed to form a schottky contact window to expose the substrate.

### BACKGROUND OF THE INVENTION

(1) Field of the Invention

This invention relates to a fabrication method of a power semiconductor structure, and more particularly relates to a fabrication method of integrating power transistors and Schottky diodes on a monolithic substrate.

(2) Description of the Prior Art

Switching speed is a dominate character for trenched power semiconductor applications. The improvement of switching speed is benefit for reducing switching loss. Nowadays, the usage of Schottky diodes is a common approach for improving switching loss.

FIG. 1 is a circuit diagram showing the technology of using the schottky diode SD1 to improve switching loss of the MOSFET T1. As shown, the body diode D1 of the MOSFET T1 is connected with the schottky diode SD1 in parallel. Since the turn-on voltage of the schottky diode SD1 is lower than that of the body diode D1, the body diode D1 would not be turned on when a positive source to drain voltage is applied crossing the MOSFET T1 and the current flow is from the source electrode S through the schottky diode SD1 to the drain electrode D.

The existence of minority carriers in the body diode D1 may cause time delay during switching. In contrast, the schottky diode SD1 has no minority carriers, and thus can prevent such time delay and is helpful for improving switching loss.

### SUMMARY OF THE INVENTION

Accordingly, it is a main object of the present invention to provide a power semiconductor structure with schottky diodes being formed together with the power transistors by using the present semiconductor processes for manufacturing power transistors.

To fulfill the above mentioned object, a fabrication method of integrating a power transistor and a schottky diode on a monolithic substrate is provided. This fabrication method can be applied to both the trenched transistor and the planar one. For the trenched transistor, firstly, a substrate of a first conductive type is provided. Then, at least a polysilicon gate and a second polysilicon structure are formed on the substrate. The second polysilicon structure has a least a portion located on an upper surface of the substrate. Thereafter, at least a body of a second conductive type and a source region of the first conductive type are formed between the polysilicon gate and the second polysilicon structure. Then, an interlayer dielectric film is formed on the polysilicon gate to define a source contact window, but the second polysilicon structure is still exposed. Afterward, at least a portion of the second polysilicon structure is removed to form a schottky contact window to expose the substrate.

According to an embodiment of the present invention, the interlayer dielectric film has a first portion and a second portion. The first portion covers the polysilicon gate and the second portion covers an upper surface of the second polysilicon structure. In addition, the space between the first portion and the second portion is utilized to define the source contact window.

According to an embodiment of the present invention, the source contact window is defined by using the space between the interlayer dielectric film and the second polysilicon structure.

As to the embodiment with the planar power transistors, the polysilicon gate and the second polysilicon structure are totally located on the upper surface of the substrate.

### BRIEF DESCRIPTION OF THE DRAWINGS

The present invention will now be specified with reference to its preferred embodiment illustrated in the drawings, in which:

FIG. 1 is a circuit diagram showing a circuit with a schottky diode to improve switching loss of the power transistor.

FIGS. 2A to 2E are schematic views showing a fabrication method of integrating trenched power transistors and schottky diodes on a monolithic substrate in accordance with a first embodiment of the present invention.

FIGS. 3A to 3E are schematic views showing a fabrication method of integrating planar power transistors and schottky diodes on a monolithic substrate in accordance with a second embodiment of the present invention.

FIGS. 4A to 4D are schematic views showing a fabrication method of integrating trenched power transistors and schottky diodes on a monolithic substrate in accordance with a third embodiment of the present invention.

FIGS. 5A to 5D are schematic views showing a fabrication method of integrating trenched power transistors and schottky diodes on a monolithic substrate in accordance with a fourth embodiment of the present invention.

FIGS. 6A to 6D are schematic views showing a fabrication method of integrating planar power transistors and schottky diodes on a monolithic substrate in accordance with a fifth embodiment of the present invention.

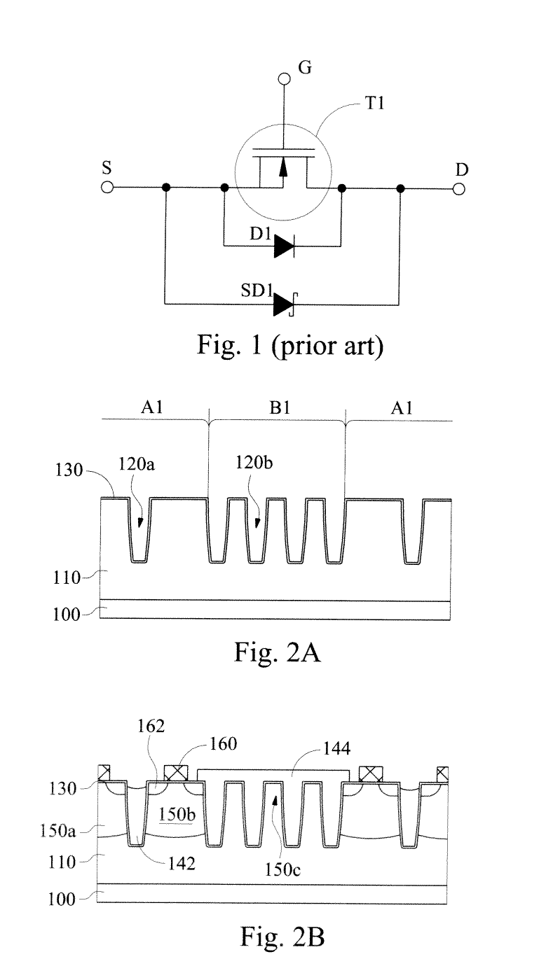

### DESCRIPTION OF THE PREFERRED EMBODIMENT

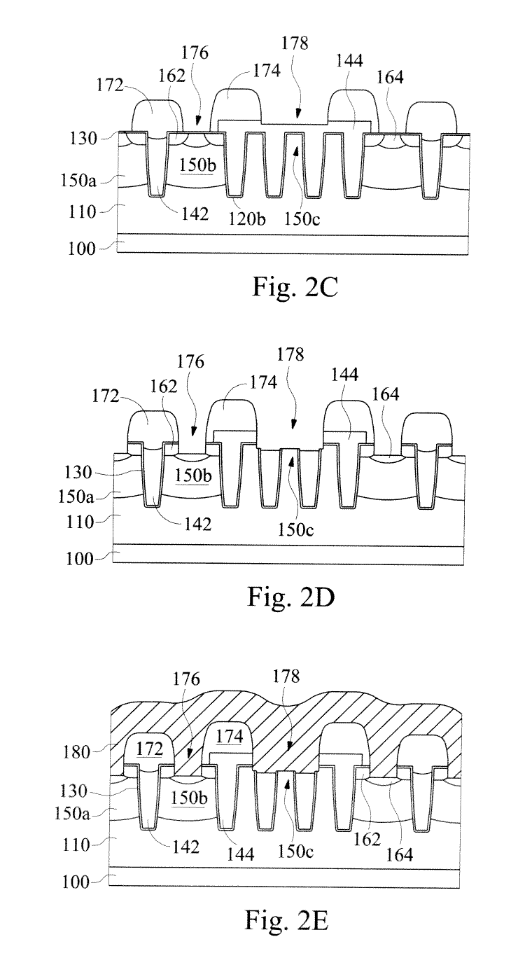

FIGS. 2A to 2E are schematic views showing a fabrication method of integrating power transistors and schottky diodes on a monolithic substrate. The trenched power transistors are used in the present embodiment. As shown in FIG. 2A, firstly, a silicon substrate 100 of a first conductive type is provided and an epitaxial layer 110 of the first conductive type is formed on the silicon substrate 100 so as to compose a base for the following fabrication steps. At least a transistor area A1 and at least a schottky diode area B1 are defined on the upper surface of the epitaxial layer 110 for locating the trenched power transistors and the schottky diodes respectively. Thereafter, at least a first trench 120a is formed in the transistor area A1 and at least two second trenches 120b are formed in the schottky diode area B1. It is a preferred embodiment to form more than three second trenches 120b in the schottky diode area B1, and four second trenches 120b are shown in the present embodiment. Then, a dielectric layer 130 is formed to line the inner surfaces of the first trench 120a and the second trenches 120b. The dielectric layer 130 on the inner surface of the first trench 120a is utilized as the gate dielectric layer for the trenched power transistors.

Next, as shown in FIG. 2B, a polysilicon layer (not shown) is deposited on the epitaxial layer 110 and then lithographic and etching processes are applied to remove the unwanted portions of the polysilicon layer so as to form a polysilicon gate 142 in the first trench 120a and a second polysilicon structure 144 on the schottky diode area B1. The polysilicon gate 142 is utilized as the gate electrode of the trenched power transistor. The second polysilicon structure 144 covers the upper surface of the epitaxial layer 110 between the second trenches 120b and has a plurality of fingers extending into the second trenches 120b.

Next, by using the second polysilicon structure 144 as an implantation mask, an ion implantation step is carried out to implant dopants of a second conductive type into the epitaxial layer 110 so as to form a body 150a in the transistor area A1 surrounding the first trench 120a and a body 150b between the first trench 120a and the second trench 120b. However, because of the second polysilicon structure 144, the body 150b would not extend to the epitaxial layer 110 between the second trenches 120b. Thereafter, a source pattern layer 160 for defining the source regions is formed on the bodies 150a, 150b by using a source mask. By using the source pattern layer 160 and the second polysilicon structure 144 as an implantation mask, another ion implantation step is carried out to implant dopants of the first conductive type into the bodies 150a and 150b so as to form a plurality of source regions 162 therein. As shown in the body 150b, two source regions 162 are formed adjacent to the first trench 120a and the second trench 120b respectively.

Referring to FIG. 2C, next, an interlayer dielectric film is deposited on the polysilicon gate 142, the epitaxial layer 110, and the second polysilicon structure 144. Then, a portion of the interlayer dielectric film above the bodies 150a, 150b is removed by using lithographic and etching processes. As shown, the remained interlayer dielectric film has a first portion 172 covering the polysilicon gate 142 and at least a second portion 174 covering the whole sidewall of the second polysilicon structure 144 but only covering a portion of the upper surface of the second polysilicon structure 144. Thereafter, by using the remained interlayer dielectric film as the mask, an ion implantation step is carried out to implant dopants of the second conductive type into the bodies 150a, 150b so as to form the heavily doped regions 164 between two neighboring source regions 162.

As shown, in the present embodiment, the second portion 174 of the interlayer dielectric film is aligned to the second trench 120b adjacent to the transistor area A1. The second portion 174 covers the respective second trench 120b but is restricted in the neighboring area thereof. In addition, the second portion 174 would not extend to the neighboring second trench 120b. For example, the width of the second portion 174 may be substantially identical to that of the first portion 172. Moreover, in the present embodiment, the interlayer dielectric film has two separated second portions 174 located at the opposite side of the schottky diode area B1, which is located between two transistor areas A1, and a schottky contact window 178 is defined by the space between the two second portions 174.

Next as shown in FIG. 2D, by using the remained interlayer dielectric film as the mask, the exposed epitaxial layer 110 is etched to form the source contact windows 176 in the bodies 150a and 150b by using the anisotropic etching technology so as to expose the source region 162 and the heavily doped region 164. In addition, the second polysilicon structure 144 is also etched in the present step to form a schottky contact window 178 therein for exposing the drift region 150c. An optional drive-in step may be added before the etching step so as to extend the heavily doped region 164 deep into the epitaxial layer 110 for guaranteeing that at least a portion of the heavily doped region 164 remained at the bottom of the source contact window 176.

As shown in FIG. 2E, after the formation of the source contact window 176 and the schottky contact window 178, a source metal layer 180 is deposited on the interlayer dielectric film and fills the source contact window 176 as well as the schottky contact window 178. Thereby, a schottky diode is formed at the bottom of the schottky contact window 178.

As mentioned above, the fabrication steps for forming the polysilicon gate 142 are also capable for forming the second polysilicon structure 144, which is functioned for preventing the dopants from being implanted into the schottky diode area B1. In addition, the second polysilicon structure 144 is electrically connected to the source electrode rather than the gate electrode. The interlayer dielectric film has the first portion 172 and the second portions 174 formed simultaneously on the polysilicon gate 142 and the second polysilicon structure 144 respectively for defining the source contact window 176 and the schottky contact window 178. The following etching steps for forming the source contact window 176 are also capable for forming the schottky contact windows 178 in the second polysilicon structure 144. Thus, the fabrication method provided in the present embodiment can be easily integrated to the fabrication method of ordinary trenched power transistor, which is benefit for reducing fabrication cost.

In addition, as shown in FIG. 2E, because the second polysilicon structure 144 is electrically connected to the source electrode through the source metal layer 180, as a negative source to drain voltage is applied, the depletion region surrounding the second polysilicon structure 144 may be extended to enhance the withstanding ability of the schottky diode. The withstanding ability would be influenced by a distance between the two second trenches 120b, As an embodiment, a distance smaller than that of two neighboring first trenches 120a is preferred.

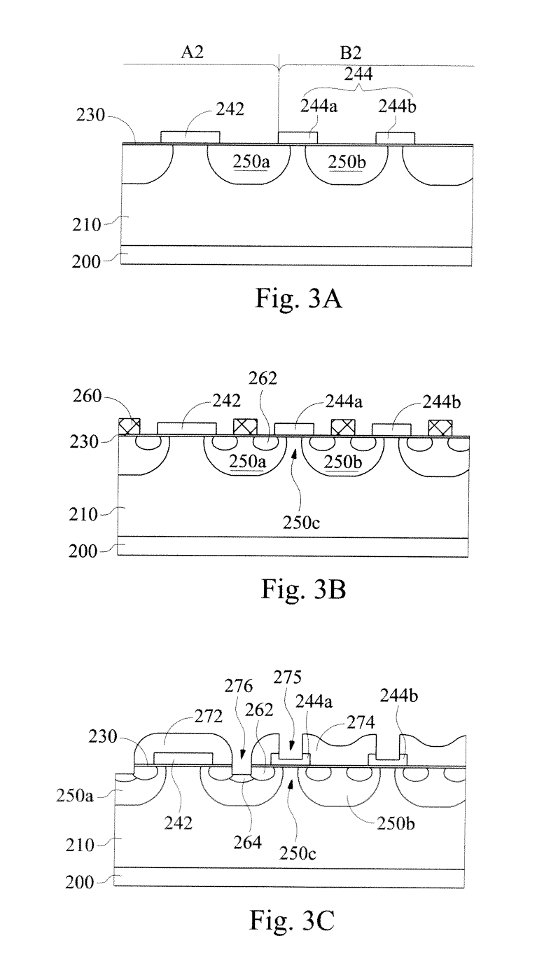

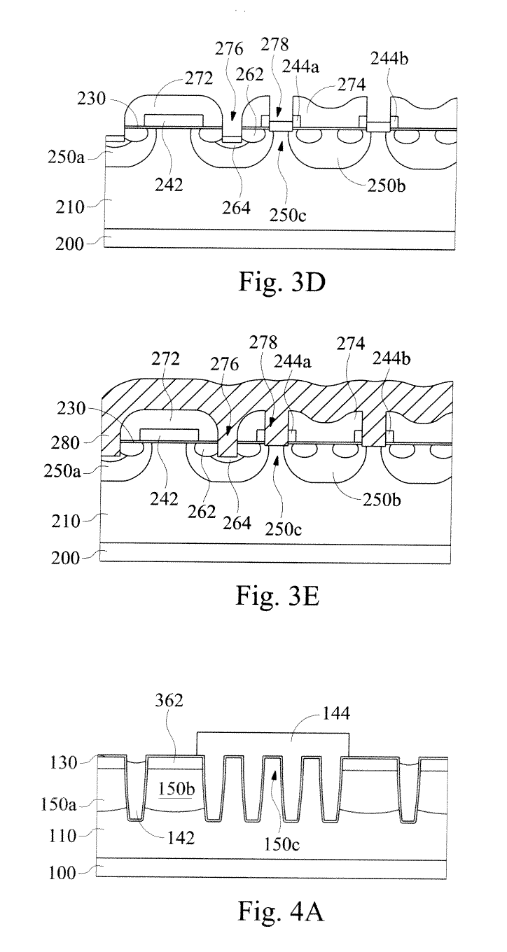

FIGS. 3A to 3E are schematic views showing a fabrication method of integrating power transistors and schottky diodes on a monolithic substrate in accordance with a second embodiment of the present invention. In the present embodiment, a planar power transistor is integrated with the schottky diode. As shown in FIG. 3A, firstly, a silicon substrate 200 of a first conductive type is provided, and an epitaxial layer 210 of the first conductive type is formed thereon to compose a base for the following fabrication steps. At least a transistor area A2 and at least a schottky diode area B2 are defined on the upper surface of the epitaxial layer 210 for locating the power transistors and the schottky diodes respectively. Afterward, a dielectric layer 230 is formed on the epitaxial layer 210.

Next, a polysilicon layer is deposited on the epitaxial layer 210, and then the lithographic and etching processes follow to form a polysilicon gate 242 and a second polysilicon structure 244 on the epitaxial layer 210. The polysilicon gate 242 is located in the transistor area A2 as the gate electrode for the planar power transistor, and the second polysilicon structure 244 is located in the schottky diode area B2. The second polysilicon structure 244 may be composed of a plurality of sections. One single second polysilicon structure 244 is also applicable to the present invention. Two separate sections 244a and 244b are shown in the present embodiment as an example. Next, by using the polysilicon gate 242 and the second polysilicon structure 244 as a mask, an ion implantation step is carried out to implant dopants of a second conductive type into the epitaxial layer 210, such that a body 250a is formed between the polysilicon gate 242 and the second polysilicon structure 244, and a body 250b is also formed between the two neighboring sections 244a, 244b of the second polysilicon structure 244.

Next, as shown in FIG. 3B, a source pattern layer 260 is formed on the bodies 250a, 250b to define the location of the source regions 262. Afterward, an ion implantation step is carried out with the source pattern layer 260, the polysilicon gate 242, and the second polysilicon structure 244 as the implantation mask so that a plurality of source regions 262 is formed in the bodies 250a, 250b.

Next, as shown in FIG. 3C, an interlayer dielectric film is deposited on the polysilicon gate 242, the epitaxial layer 210, and the second polysilicon structure 244. Thereafter, the unwanted portion of the interlayer dielectric film is removed by using lithographic and etching processes. The remained interlayer dielectric film has a first portion 272 covering the polysilicon gate 242 and at least a second portion 274 covering the second polysilicon structure 244. A plurality of opens 275 are also formed in the second portion 274 for exposing the sections 244a, 244b of the second polysilicon structure 244. The opens 275 are utilized for defining the location of the schottky contact window. In addition, a source contact window 276 is formed in the space between the first portion 272 and the second portion 274 of the interlayer dielectric film for exposing the source region 262. Thereafter, by using the remained interlayer dielectric film and the second polysilicon structure 244 as the mask, an ion implantation step is performed to implant dopants of the second conductive type into the bodies 250a, 250b to form the heavily doped region 264.

Next, as shown in FIG. 3D, by using the first portion 272 and the second portion 274 of the interlayer dielectric film as the mask, the second polysilicon structure 244 is etched by using anisotropic etching technology for example so as to form at least a schottky contact window 278 penetrating the second polysilicon structure 244 to expose the drift region 250c below the sections 244a, 244b. Finally, as shown in FIG. 3E, a source metal layer 280 is deposited on the interlayer dielectric film and fills the source contact window 276 as well as the schottky contact window 278 so that a schottky diode is formed at the bottom of the schottky contact window 278.

It is noted that because the epitaxial layer 210 between the first portion 272 and the second portion 274 is exposed during the etching step as shown in FIG. 3D for forming the schottky contact window 278, the bottom of the source contact window 276 would be extended downward. To make sure that at least a portion of the heavily doped region 264 is remained at the bottom of the source contact window 276, referring to FIGS. 3C and 3D, a two-step etching process may be used for forming the source contact window 276 and the schottky contact window 278. As shown in FIG. 3C, after the first etching step, the bottom of the source contact window 276 has already reached the bodies 250a, 250b but the bottom of the schottky contact window 278 is still located in the second polysilicon structure 244. Thereafter, as shown in FIG. 3D, after implanting second conductive type dopants to form the heavily doped region 264 below the source contact window 276, the second etching step follows to extend the schottky contact window 278 to the drift region 250c below the second polysilicon structure 274. The above etching process mentioned above is also capable to increase the depth of the heavily doped region 264 and prevent the heavily doped region 264 from being totally removed when a single etching step with large etching depth is used.

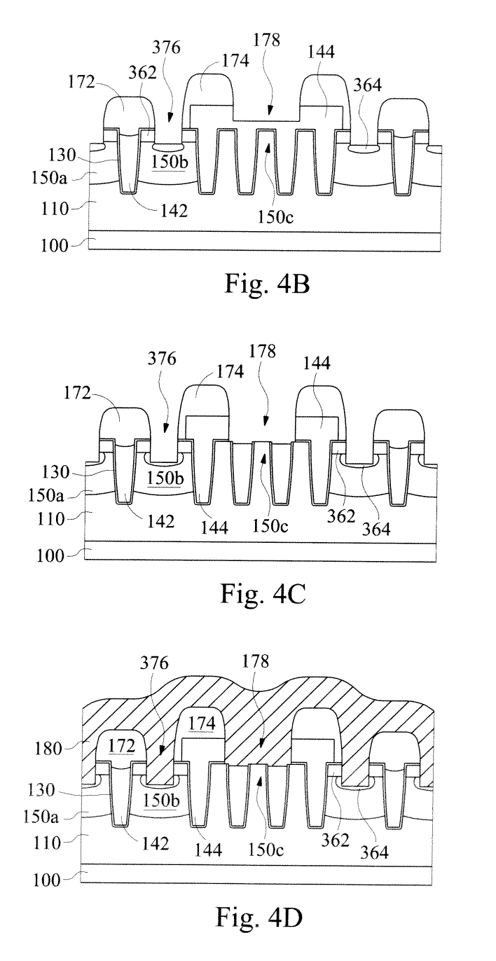

FIGS. 4A to 4D are schematic views showing a fabrication method of integrating power transistors and schottky diodes on a monolithic substrate in accordance with a third embodiment of the present invention. In the present embodiment, the trenched power transistor is integrated with the schottky diode. The fabrication step as shown in FIG. 4A is next to the fabrication step of FIG. 2A. Referring to FIGS. 4A and 4B, a major difference between the present embodiment and the first embodiment is that the present embodiment skips the formation of source pattern layer 160 and a blanket implantation step is used to form the source region 362. In addition, the implantation step for forming heavily doped region 364 of the present embodiment is later than the fabrication step for forming the source contact window 376 in the bodies 150a, 150b for expose the source region 362. The following steps as shown in FIGS. 4C and 4D are similar to the fabrication steps of FIGS. 2D and 2E of the first embodiment, and thus are not repeated here.

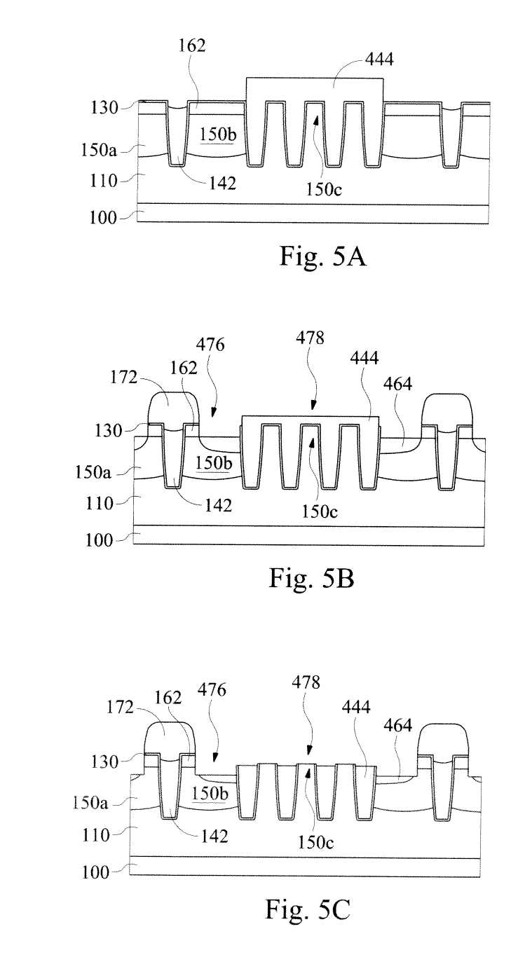

FIGS. 5A to 5D are schematic views showing a fabrication method of integrating power transistors and schottky diodes on a monolithic substrate in accordance with a fourth embodiment of the present invention. In the present embodiment, the trenched power transistor is integrated with the schottky diode. The fabrication step as shown in FIG. 5A is next to the fabrication step of FIG. 2A. Referring to FIG. 5A, a major difference between the present embodiment and the first embodiment is that the sidewall of the second polysilicon structure 444 of the present embodiment is substantially aligned to the boundary between the second trench 120b and the body 150b, which is also the sidewall of the second trench 120b. In addition, as shown in FIG. 5B, the interlayer dielectric film in the present embodiment does not have the second portion 174 located on the second polysilicon structure 444 as shown in FIG. 2C. The source contact window 476 of the present invention is defined in the space between the first portion 172 and the second polysilicon structure 444.

As shown in FIG. 5B, after the first portion 172 of the interlayer dielectric film is formed to cover the polysilicon gate 142, an etching step is carried out directly by using the interlayer dielectric film as the mask so as to form the source contact window 476 in the epitaxial layer 110. Thereafter, an ion implantation step is performed with the epitaxial layer 110 being shielded by the interlayer dielectric film and the second polysilicon structure 444 so as to form a heavily doped region 464 of second conductive type at the bottom of the source contact window 476. It should be noted that the second polysilicon structure 444 would be thinned in the present etching step. To prevent the second polysilicon structure 444 from being totally removed, the second polysilicon structure 444 with enough thickness is necessary.

As shown in FIG. 5C, after the heavily doped region 464 is formed at the bottom of the source contact window 476, the second polysilicon structure 444 is removed by etching so as to expose the drift region 105c below the second polysilicon structure 444. That is, a schottky contact window 478 is formed. According to the present embodiment, a portion of the epitaxial layer 110 is also removed in the etching step for removing the polysilicon structure 444 and thus the depth of the source contact window 476 would be increased. To prevent the heavily doped region 464 at the bottom of the source contact window 576 from being totally removed, a thermal drive-in step may be added prior to the etching step to extend the range of the heavily doped region 464. Finally, as shown in FIG. 5D, a source metal layer 180 is deposited on the first portion 172 of the interlayer dielectric film, the remained second polysilicon structure 444, and the drift region 150c. A schottky diode is thus formed at the schottky contact window 478.

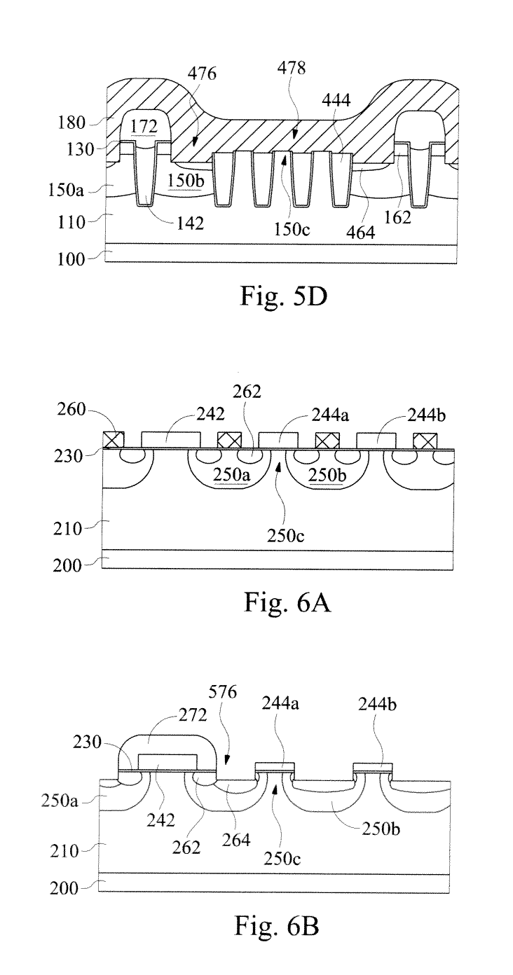

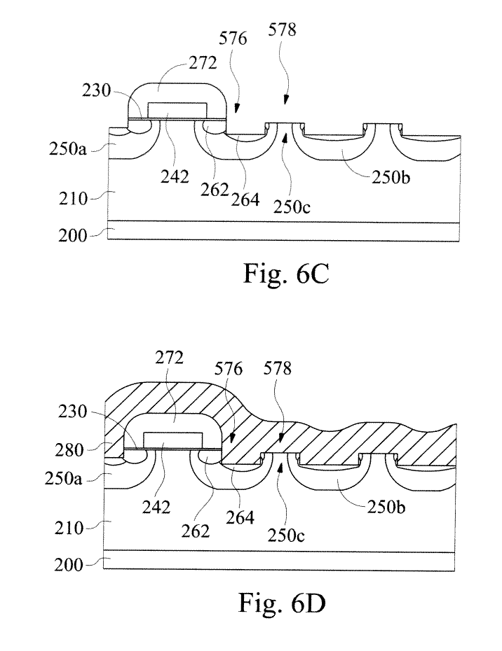

FIGS. 6A to 6D are schematic views showing a fabrication method of integrating power transistors and schottky diodes on a monolithic substrate in accordance with a fifth embodiment of the present invention. In the present embodiment, the planar power transistor is integrated with the schottky diode. The fabrication step of FIG. 6A follows the fabrication of FIG. 3B. Referring to FIG. 6A, a major difference between the present embodiment and the second embodiment is that, the etched interlayer dielectric film of the present embodiment does not have the second portion 274 as shown in FIG. 3C, and the source contact window 576 of the present embodiment is defined by using the first portion 272 of the interlayer dielectric film and the section 244a of the second polysilicon structure 244.

Referring to FIG. 6B, after forming the first portion 272 of the interlayer dielectric film to shield the polysilicon gate 242, an etching step is carried out by using the interlayer dielectric film as the mask to etch the epitaxial layer 210 so as to form the source contact window 576 between the interlayer dielectric film and the second polysilicon structure 244. It is noted that the exposed second polysilicon structure 244 would be thinned in the present etching step. To prevent the second polysilicon structure 244 from being totally removed, the second polysilicon structure 244 with enough thickness should be formed.

After the formation of the source contact window 576, an ion implantation step follows for implanting second conductive type dopants to the bodies 250a, 250b so as to form the heavily doped region 564 at the bottom of the source contact window 576. Thereafter, a thermal drive-in step is performed to extend the heavily doped region 564 deep into the bodies 250a, 250b. Then, as shown in FIG. 6C, the second polysilicon structure 244 on the epitaxial layer 210 is removed by etching so as to expose the drift region 250c below the second polysilicon structure 244. Thereby, the schottky contact window 578 is formed. Finally, as shown in FIG. 6D, a source metal layer 280 is deposited on the first portion 272 of the interlayer dielectric film and the drift region 250c, and fills the source contact window 576.

While the preferred embodiments of the present invention have been set forth for the purpose of disclosure, modifications of the disclosed embodiments of the present invention as well as other embodiments thereof may occur to those skilled in the art. Accordingly, the appended claims are intended to cover all embodiments which do not depart from the spirit and scope of the present invention.

What is claimed is:

1. A fabrication method of integrating a power transistor and a schottky diode on a monolithic substrate comprising the steps of:
providing a substrate of a first conductive type;
forming at least a polysilicon gate and a second polysilicon structure on the substrate, the second polysilicon structure having a least a portion located on an upper surface of the substrate;
forming at least a body of a second conductive type and a source region of the first conductive type between the polysilicon gate and the second polysilicon structure;
forming an interlayer dielectric film on the polysilicon gate to define a source contact window and the second polysilicon structure being exposed; and
removing at least a portion of the second polysilicon structure to form a schottky contact window to expose the substrate.

2. The fabrication method of claim 1, wherein step of forming the polysilicon gate and the second polysilicon structure on the substrate comprises:
forming at least a first trench and at least two second trenches in the substrate;
forming a dielectric layer on inner surfaces of the first trench and the second trenches;
forming at least a polysilicon gate in the first trench; and
forming a second polysilicon structure with a plurality of fingers filled into the second trenches on the substrate between the second trenches.

3. The fabrication method of claim 2, wherein the number of the second trench is equal to or greater than three.

4. The fabrication of claim 1, wherein the step of forming the source region comprises:
forming a pattern layer on the body to define at least two source regions adjacent to the first trench and the second trench respectively.

5. The fabrication method of claim 1, wherein the interlayer dielectric film has a first portion and a second portion, the first portion covers the polysilicon gate, the second portion covers an upper surface of the second polysilicon structure, and an open between the first portion and the second portion is utilized to define the source contact window.

6. The fabrication method of claim 1, after the step of defining the source contact window, further comprising the step of implanting dopants of the second conductive type through the source contact window to form a heavily doped region in the body.

7. The fabrication method of claim 5, wherein the second portion is substantially aligned to the respective second trench.

8. The fabrication method of claim 5, wherein during the step of forming the schottky contact window, the source contact window is simultaneously formed in the body.

9. The fabrication method of claim 5, wherein before the step of forming the schottky contact window, the source contact window is formed in the body.

10. The fabrication method of claim 2, wherein a sidewall of the second polysilicon structure is aligned to a boundary between the second trench and the body.

11. The fabrication method of claim 2, wherein the source contact window is defined by a space between the interlayer dielectric film and the second polysilicon structure.

12. The fabrication method of claim 2, wherein the polysilicon gate and the second polysilicon structure are formed simultaneously.

13. The fabrication method of claim 1, wherein the polysilicon gate and the second polysilicon structure are totally located on the upper surface of the substrate.

14. The fabrication method of claim 1, after the step of forming the interlayer dielectric film, further comprising the step of etching the body through the interlayer dielectric film to form the source contact window.

15. The fabrication method of claim 13, wherein the step of forming the schottky contact window is to remove the second polysilicon structure totally.
